(19) United States
(12) Patent Application Publication
(10) Pub. No.: US 2026/0323972 A1
(43) Pub. Date: Oct. 15, 2026

(54) DEEP METAL-INSULATOR-METAL CAPACITOR

(71) Applicant: Taiwan Semiconductor Manufacturing Company, Ltd., Hsinchu (TW)

(72) Inventors: Yu-Cheng Tsai, Tainan City (TW); Meng-Hsien Lin, Tainan City (TW); Hsing-Chih Lin, Tainan City (TW); Ming-Tsong Wang, Taipei City (TW); Jen-Cheng Liu, Hsin-Chu City (TW); Shih-Rong Yang, Hsinchu (TW)

(21) Appl. No.: 19/719,374

(22) Filed: Jun. 25, 2026

Related U.S. Application Data
(63) Continuation of application No. 18/965,192, filed on Dec. 2, 2024.

(51) Int. Cl. H10D 1/68; H10W 20/40; H10W 20/41; H10W 20/42

(52) U.S. Cl. CPC H10D 1/716; H10W 20/42; H10W 20/435; H10W 20/496

(57) ABSTRACT

Some embodiments relate to a device including a semiconductor substrate, and an interconnect structure disposed over the semiconductor substrate. The interconnect structure includes a lower metal line, an intermediate metal line, and an upper metal line, and a plurality of metal vias. A first electrode disposed in the interconnect structure includes a first lateral portion and a protrusion that extends downward from the first lateral portion. The first lateral portion is disposed over an upper surface of the upper metal line, and the protrusion extends below a lower surface of the lower metal line. A second electrode is disposed in the interconnect structure, matingly engages the first electrode, and has a lower surface that is below a lower surface of the first electrode. A dielectric laterally surrounds an inner sidewall structure of the second electrode to separate the second electrode from an outer sidewall structure of the first electrode.

### REFERENCE TO RELATED APPLICATION

This Application is a Continuation of U.S. Application number Ser. No. 18/965,192, filed on Dec. 2, 2024, the contents of which are hereby incorporated by reference in their entirety.

### BACKGROUND

Capacitors are a passive circuit component used in imaging, memory, and many more applications. One common type of capacitor in integrated circuits is a metal-insulator-metal (MIM) capacitor. A MIM capacitor has a metal bottom layer, a metal top layer, and a dielectric layer separating the metal bottom layer from the metal top layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a device including a MIM capacitor in accordance with some embodiments.

FIG. 2 illustrates a cross-sectional view of some embodiments of a device including a MIM capacitor in accordance with some embodiments.

FIG. 3A illustrates a cross-sectional view of some embodiments of a device including a MIM capacitor in accordance with some embodiments.

FIG. 3B illustrates a cross-sectional view of some embodiments of a device including a MIM capacitor in accordance with some embodiments.

FIG. 4 illustrates a top view of some embodiments of the capacitor of FIG. 3A in accordance with some embodiments.

FIG. 5 illustrates another top view of some embodiments of the capacitor of FIG. 3A in accordance with some embodiments.

FIG. 6 illustrates a cross-sectional view of some embodiments of a capacitor in accordance with some embodiments.

FIG. 7 illustrates a cross-sectional view of some embodiments of a capacitor in accordance with some embodiments.

FIG. 8 illustrates a three-dimensional cut-away view of an upper electrode of a MIM capacitor consistent with FIG. 3A and an inset portion of FIG. 5.

FIG. 9 illustrates a three-dimensional cut-away view of a lower electrode of a MIM capacitor consistent with FIG. 3A and an inset portion of FIG. 5.

FIGS. 10A-10B, 11A-11B, 11C-11D, 12A-12B, 13A-13B, 14A-14B, 15A-15B, 16A-16B, 17A-17B, and 18A-18B illustrate a series of cross-sectional views (FIGS. 10A, 11A, 11C, 12A, 13A, 14A, 15A, 16A, 17A, and 18A) and top views (FIGS. 10B, 11B, 11D, 12B, 13B, 14B, 15B, 16B, 17B, and 18B) that collectively illustrate a manufacturing flow for making a capacitor in accordance with some embodiments.

FIG. 19 illustrates an additional step of the manufacturing flow where the die of FIG. 18A is bonded to another die according to some embodiments.

FIG. 20 illustrates a flowchart of some embodiments of a method of forming a device including a MIM capacitor.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A MIM capacitor includes a bottom metal layer, a top metal layer, and a capacitor dielectric separating the bottom metal layer from the top metal layer. The MIM capacitor may extend horizontally across an interlayer dielectric (ILD) layer, and vertically through the ILD layer. The MIM capacitor extending both horizontally and vertically increases the surface area of the capacitor dielectric and the resulting capacitance of the capacitor. The present disclosure provides MIM capacitors that have increased depth to increase capacitance compared to previous approaches. Some embodiments of the present disclosure also have a closely stacked pattern when the MIM capacitor is viewed from a top view, and this closely stacked pattern can include a series of cylinders, ellipsoids, or polygons, that further facilitates increased capacitance compared to previous approaches.

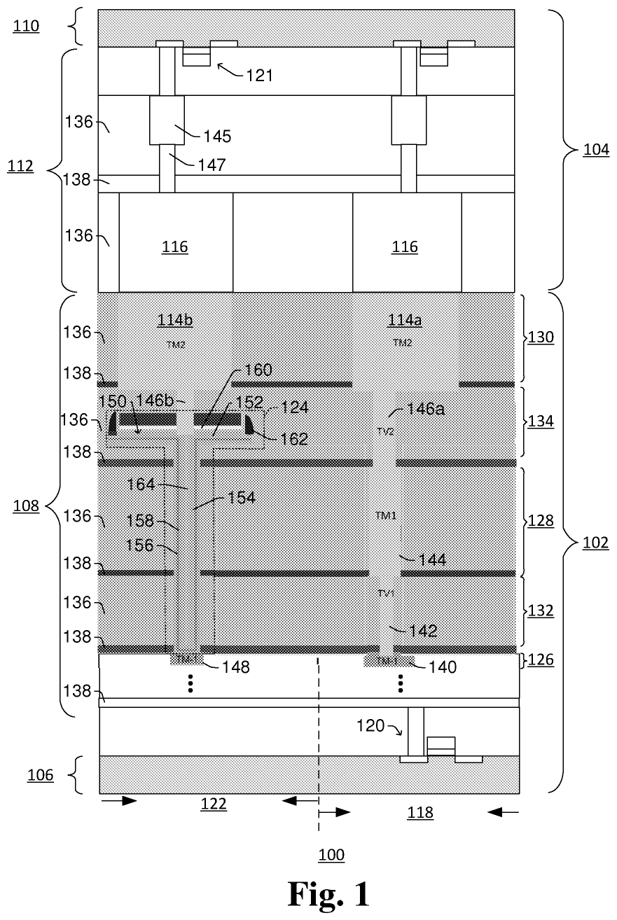

FIG. 1 illustrates a cross-sectional view of some embodiments of a device 100 including a MIM capacitor according to some embodiments. The device 100 includes a first die 102 and a second die 104 stacked over the first die. The first die 102 includes a semiconductor substrate 106 and an interconnect structure 108 over the semiconductor substrate 106. The second die 104 includes a second semiconductor substrate 110 optionally including semiconductor devices 121, and a second interconnect structure 112 beneath the second semiconductor substrate 110. The second interconnect structure 112 can include metal lines (e.g., 145) and vias (e.g., 147). The top of the interconnect structure 108 includes conductive bond pads 114 and/or other bonding structures that are bonded to conductive bond pads 116 and/or other bonding structures on the bottom of the second interconnect structure 112, such that the first die 102 is physically and electrically coupled to the second die 104. Additional die can also be arranged over the second die 104 and/or beneath the first die 102 to establish a so-called three-dimensional integrated circuit.

For the first die 102, the semiconductor substrate 106 includes a logic region 118 that includes semiconductor devices 120 (e.g., transistors) that are connected to one another by conductive features in the interconnect structure 108. The semiconductor substrate 106 also includes a capacitor region 122, which in some examples can be devoid of semiconductor devices in the substrate, and which includes a region of the interconnect structure that includes a MIM capacitor 124. In general, the interconnect structure 108 includes a number of metal line/pad layers (e.g., 126, 128, 130) and via layers (e.g., 132, 134) arranged within an inter-layer dielectric (ILD) structure 136. The metal line layers can include a lower metal line (e.g., 126), an intermediate metal line (e.g., 128), and an upper metal line/pad (e.g., 130) disposed at different heights from one another. Etch stop layers 138 are disposed at the top and/or bottom of the various metal line layers and/or via layers. In some embodiments, the semiconductor devices 120, 121 include a transistor device (e.g., a planar FET, a FinFET, a gate-all-around (GAA) device, bi-polar junction transistor (BJT)), but could also include diodes, etc.

Within the logic region 118, the interconnect structure 108 includes a first conductive feature 140 disposed at a first conductive feature height over a surface of the semiconductor substrate 106. A first via 142 is disposed at a first via height over the surface of the semiconductor substrate. The first via 142 is coupled to the first conductive feature 140, and the first via height is greater than the first conductive feature height. A first metal line 144 is disposed at a first metal line height over the surface of the semiconductor substrate. The first metal line 144 is coupled to the first via 142, and the first metal line height is greater than the first via height. A second via 146a is disposed at a second via height over the surface of the semiconductor substrate. The second via 146a is coupled to the first metal line 144, and the second via height is greater than the first metal line height. A second metal line or bond pad 114a is disposed at a second metal line height over the surface of the semiconductor substrate. The second metal line or bond pad 114a is coupled to the second via 146a, and the second metal line height is greater than the second via height.

Within the capacitor region 122, the interconnect structure 108 includes a second conductive feature 148 disposed at the conductive feature height over the surface of the semiconductor substrate. The second conductive feature 148 is laterally spaced from the first conductive feature 140. The MIM capacitor 124 includes a first electrode 150 including a first lateral portion 152 and a protrusion 154 that extends downward from the first lateral portion 152 and is over the second conductive feature 148. The first lateral portion 152 of the first electrode is disposed at a first electrode height that is greater than the first metal line height. The protrusion 154 extends down to the first via height. A second electrode 156 is disposed over the second conductive feature 148 and extends upward from the second conductive feature 148 to over the first metal line height. A dielectric 158 laterally surrounds an inner sidewall structure of the second electrode 156 to separate the inner sidewall structure of the second electrode 156 from an outer sidewall structure of protrusion 154 of the first electrode 150. Thus, in some examples, the second electrode 156 matingly engages the first electrode 150 in a male/female or female/male manner. A dielectric 164, such as an air gap, can be optionally present in a central region of the protrusion 154. A hard mask 160 can cover an upper surface of the lateral portion 152 of the first electrode 150, and spacers 162 are arranged on outer sidewalls of the hard mask 160 and lateral portion of the first electrode 150. A via 146b extends down from the upper metal or bond pad 114b to the top electrode 150 and extends through the hard mask 160.

In some embodiments, a depth of the first electrode 150 and/or second electrode 156 is greater than the combined height of the lower metal layer 128 and lower via layer 132. Thus, the depth of the first electrode 150 and/or second electrode 156 exceeds a height that separates two etch stop layers 138. Further, in some embodiments, the depth of the first and/or second electrode can be between 1.5 micrometers and 2.0 micrometers. Because this depth is greater than previous MIM capacitors, the structure of FIG. 1 can provide an increased capacitance compared with previous capacitors.

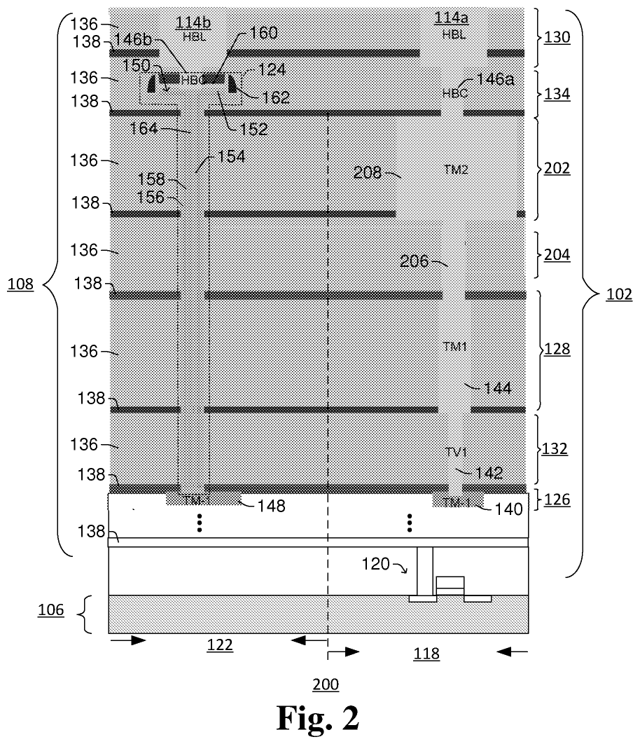

FIG. 2 illustrates a cross-sectional view of some embodiments of a device 200 including a MIM capacitor 124 according to some embodiments. For simplicity and clarity, FIG. 2 omits a second die as was illustrated in FIG. 1, but a second die can still be stacked over the first die similar to as in FIG. 1.

In FIG. 2's device 200, the depth of the MIM capacitor 124 is deeper than that of FIG. 1, which provides the MIM capacitor 124 of device 200 with an increased capacitance relative to the MIM capacitor 124 of FIG. 1. In the example of FIG. 2, the depth of the first electrode 150 and/or second electrode 156 is greater than the combined height of the lower metal layer 128, lower via layer 132, an intermediate metal layer 202, and an intermediate via layer 204. Thus, the depth of the first electrode 150 and/or second electrode 156 exceeds a total height measured between four etch stop layers 138. The depth of the first electrode 150 and/or second electrode 156 could also be even deeper than illustrated in FIG. 2, and could span 5, 6, 7, 8, 9, 10, or even more etch stop layers. In some cases, the depth of the first electrode 150 and/or second electrode 156 can be between 3 micrometers and 4 micrometers.

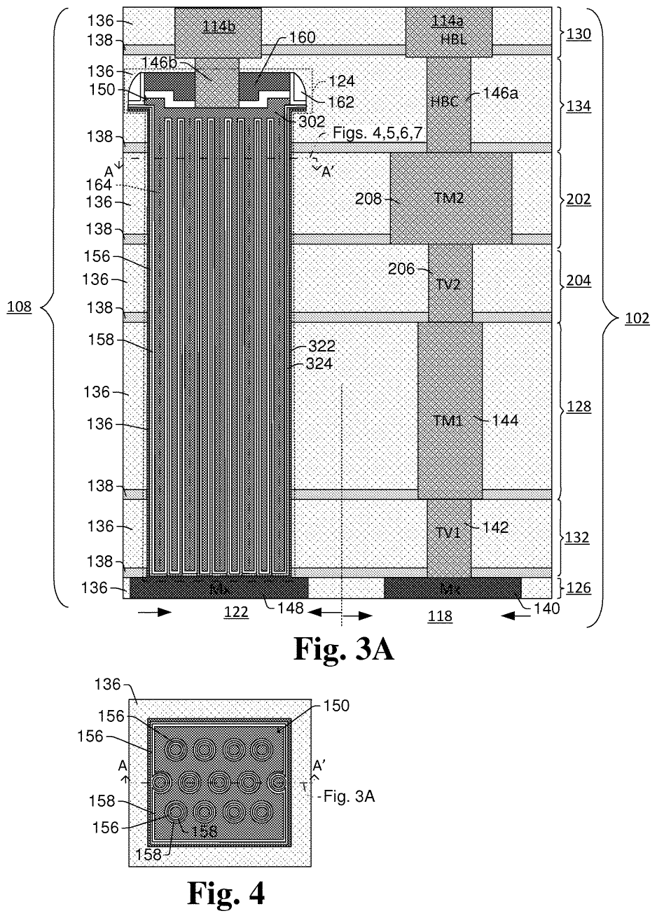

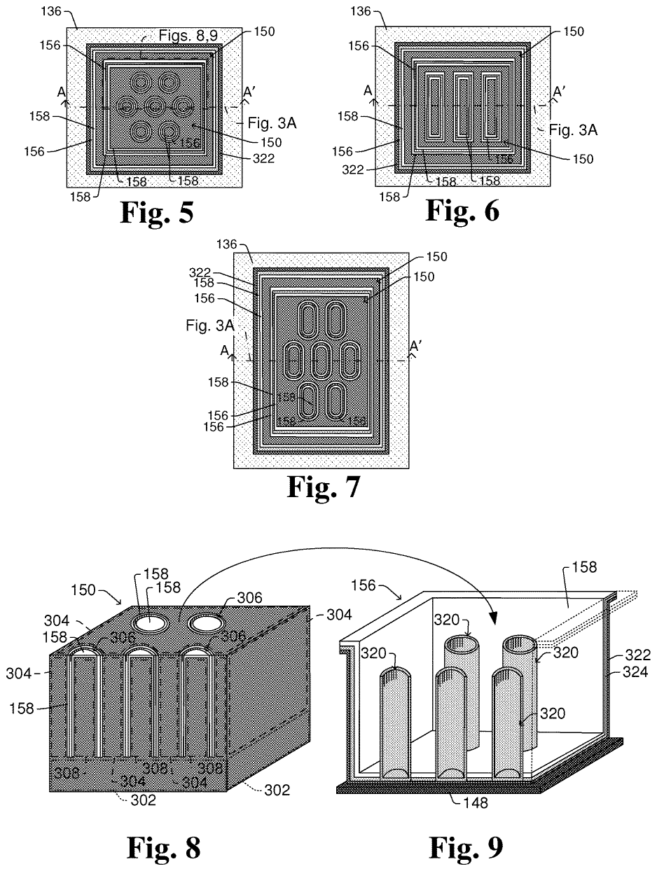

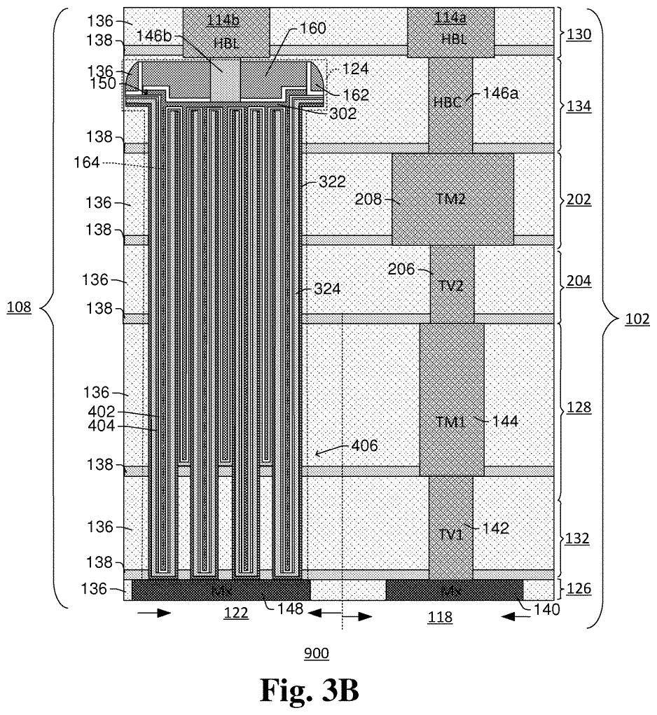

FIG. 3A illustrates another device 300 in accordance with some examples. FIG. 3A is now described concurrently along with FIGS. 4-7, which show various examples of top views consistent with FIG. 3A. FIG. 3A is also described concurrently along with FIGS. 8-9, which show a three dimensional exploded view of the first (e.g., upper) electrode (FIG. 8) and second (e.g., lower) electrode (FIG. 9), which have a dielectric separating the first and second electrodes. FIG. 8 is inverted relative to FIG. 9 to better show the various features of the first electrode. For simplicity and clarity, FIG. 3A omits a second die and a substrate as was illustrated in FIG. 1, but these elements be included similar to as in FIG. 1.

FIG. 3A's device includes a first electrode 150 disposed in the interconnect structure 108. The first electrode 150 includes a first lateral portion 302 and a manifold portion 304 (see FIG. 8). The manifold portion 304 extends downward from the first lateral portion 302, and includes a plurality of openings 306 defined by inner sidewalls of the manifold portion 304. A plurality of protrusions 308 extend downward from the first lateral portion 302 and are arranged respectively within the plurality of openings 306 of the manifold portion. In the example of FIGS. 4, 5 and 8, these protrusions 308 are circular when viewed from above, but the protrusions can also be square, square with rounded corners, rectangular (FIG. 6), rectangular with rounded corners or oval (FIG. 7), and/or other polygonal shape, when viewed from a top view.

The second electrode 156 includes a plurality of tubes 320 (see FIG. 9) that extend upward from over the first conductive feature to over the second metal line height. The plurality of tubes each have a perimeter that is circular, square, square with rounded corners, rectangular, oval or rectangular with rounded corners, and/or other polygonal shape, when viewed from a top view. The size of each tube 320 corresponds to an opening 306 in the manifold portion, such that the tubes 320 matingly engage the openings 306 in the manifold portion. Thus, the protrusions 308 in the manifold portion of the first electrode 150 are received within the inner volume of the tubes 320; and the tubes 320 are received within the openings 306 defined by the inner sidewalls of the manifold portion. The second electrode 156 includes barrier layer 322 and a first capacitor bottom electrode layer 324. The barrier layer 322 can be or comprise tantalum or tantalum nitride, and is disposed along inner sidewalls of a recess in which the MIM capacitor is formed. The first capacitor bottom electrode layer 324 can be or comprise titanium nitride, and is conformally disposed over the barrier layer 322.

The dielectric 158 is arranged along the inner sidewalls of the manifold portion 304 and along outer sidewalls of the manifold portion 304. The dielectric 158 is also arranged along inner and outer sidewalls of the plurality of tubes, and/or is arranged on outer sidewalls of the protrusions 308. The dielectric 158 can be silicon dioxide or a high-k dielectric material. In some examples, the manifold portion 304 and the tubes 320 have the same height as one another.

FIG. 3B illustrates a cross-sectional view of some embodiments of a device including another MIM capacitor in accordance with some embodiments. In this example, the manifold portion 304 has a different height/length from the tubes 320. Thus, the tubes extend from the second conductive feature 148 up to the lateral portion of the first electrode 150, while a portion 406 of the manifold portion stops at an etch stop layer corresponding to the bottom of metal line 144. Compared to the example of FIG. 3A, the dielectric in this example includes a first dielectric layer 402 and a second dielectric layer 404. The first dielectric layer 402 can be the same material as the second dielectric layer 404, or can be a different material.

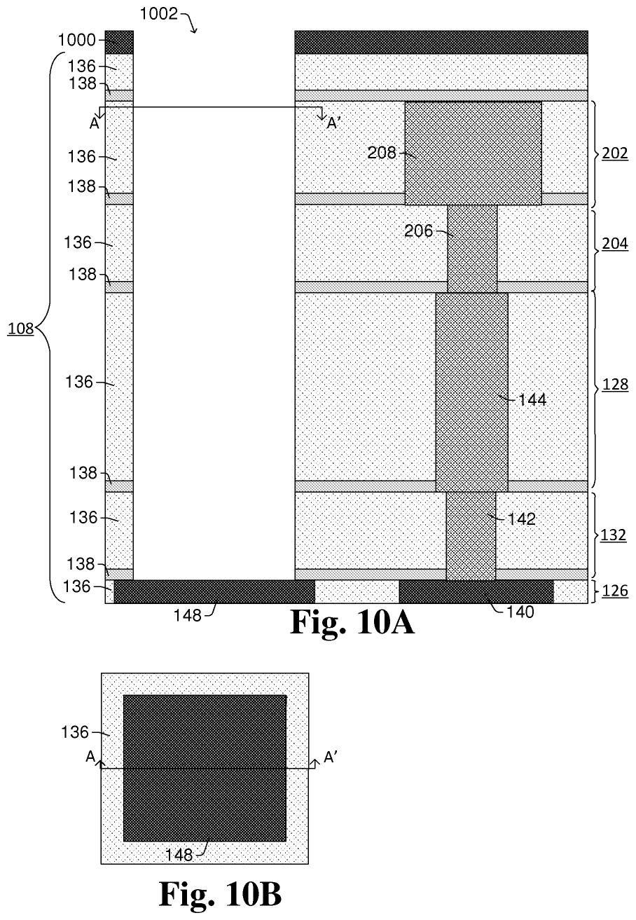

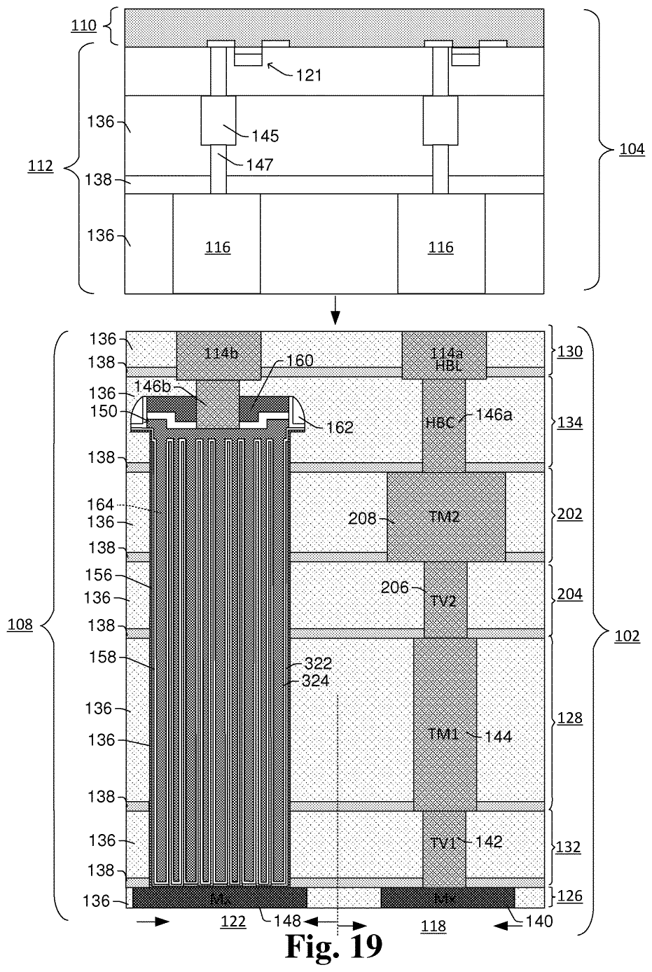

FIGS. 10A-10B through 18A-18B illustrate a series of cross-sectional views (FIGS. 10A-18A) and corresponding top views (FIGS. 10B-18B) that collectively illustrate a method of forming a wafer and/or die including a MIM capacitor according to some embodiments. FIG. 19 illustrates an additional step where the die of FIG. 18A is bonded to another wafer and/or die according to some embodiments. Although these figures are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in FIGS. 10A-10B, an interconnect structure including first and second conductive features 140, 148, a first via 142, a first metal line 144, a second via 206, and a second metal line 206 are formed within a dielectric structure 130 over the surface of the semiconductor substrate. Although not shown in FIG. 10A-10B for simplicity, the substrate may be arranged as previously shown in FIGS. 1-2, and may be any suitable type of substrate. For example, the substrate may be a semiconductor wafer, one or more dies on a wafer, or any other suitable type of semiconductor body and/or epitaxial layers. In some embodiments, the substrate is or comprises monocrystalline silicon, sapphire, the like, or any combination of the foregoing. In some embodiments, the first metal line 144, a second via 206, and a second metal line 208 are or comprise a conductive material, such as copper (Cu), titanium (Ti), aluminum (Al), tungsten, the like, or a combination of the foregoing. In some embodiments, the dielectric structure includes multiple interlayer dielectric layers 136, and various etch stop layers 138. The interlayer dielectric layer 136 is or comprises an insulator, such as a low-k dielectric material, silicon dioxide (SiO₂), or the like. The etch stop layer 138 is or comprises a nitride or carbide, such as silicon nitride (Si₃N₄), silicon carbide (SiC), silicon oxynitride, or the like.

As shown in the cross-sectional view of FIG. 10A, a first masking layer 1000 is formed over the uppermost ILD layer 136. The first masking layer 1000 can be spun-on to the substrate as a liquid, hardened, and then patterned. In some embodiments, the first masking layer 1000 is or comprises a photoresist and/or the first masking layer 1000 is patterned using photolithography. After the first masking layer 1000 is patterned, a first etching process is performed with the first masking layer 1000 in place to form a MIM capacitor recess 1002.

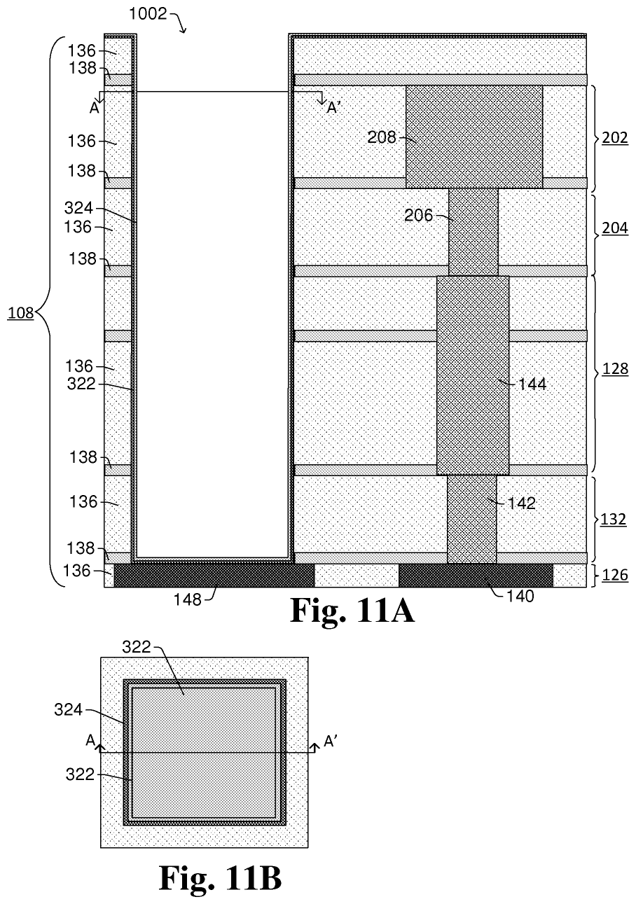

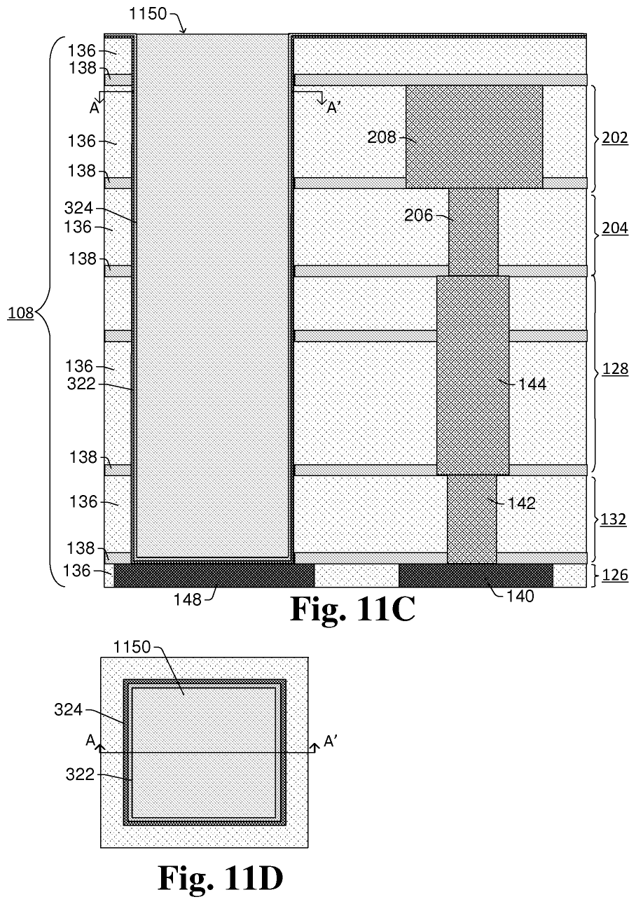

As shown in the cross-sectional and top views of FIGS. 11A-11B, after the MIM capacitor recess 1002 is formed, a barrier layer 322, such as a tantalum or tantalum nitride layer, is formed along exposed surfaces of the MIM capacitor recess 1002 and over an upper surface of the ILD layer. Thus, the barrier layer 322 extends over the second conductive feature, and along inner sidewalls of the dielectric structure. A first capacitor bottom metal (CBM1) layer 324, such as titanium nitride, is then conformally formed over the barrier layer 322.

As shown in the cross-sectional and top views of FIG. 11C-11D, after the CBM1 layer 324 is formed, a sacrificial layer 1150 is then formed to fill the MIM capacitor recess, and the sacrificial layer is then patterned to form a series of shapes 1200 in the MIM capacitor recess. A CMP operation may be carried out after the sacrificial layer 1150 is formed to planarize or level an upper surface of the sacrificial layer 1150 and CBM1 layer 324. In some embodiments, the sacrificial layer is or comprises an insulator, such as silicon dioxide (SiO₂) or the like.

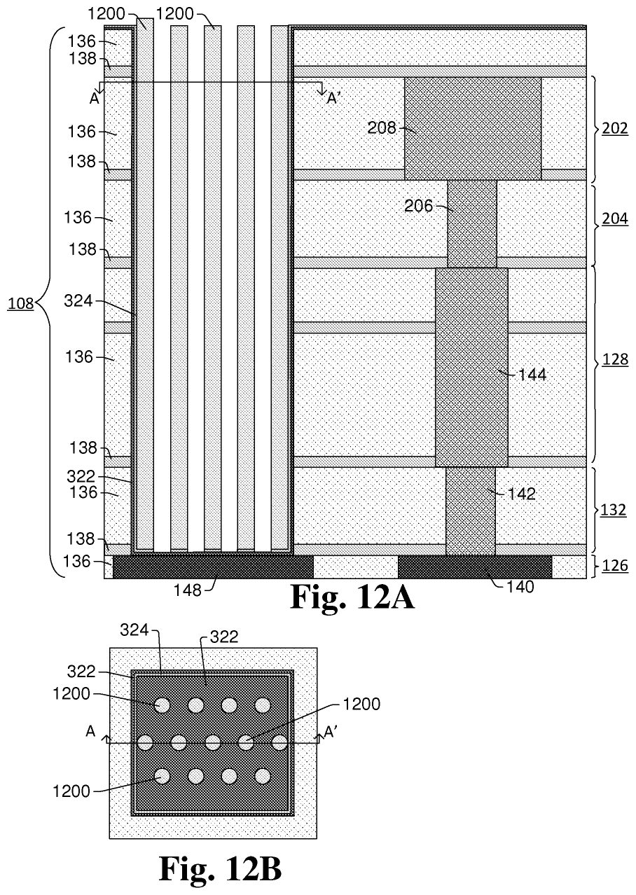

As shown in the cross-sectional and top views of FIGS. 12A-12B, the sacrificial layer is then patterned to form a series of shapes 1200 in the MIM capacitor recess. In the example of FIG. 12, the sacrificial layer is patterned to form a series of cylinders 1200 that have circular perimeters when view from a top view. In other examples, the patterned shapes 1200 could be ovals, rectangles, squares, or other polygons, any of which could have rounded corners or square corners. The sacrificial layer can be patterned by forming a photoresist mask over an upper surface of the sacrificial layer, and then carrying out an etch, such as a dry etch (e.g., plasma etch), with the photoresist mask in place.

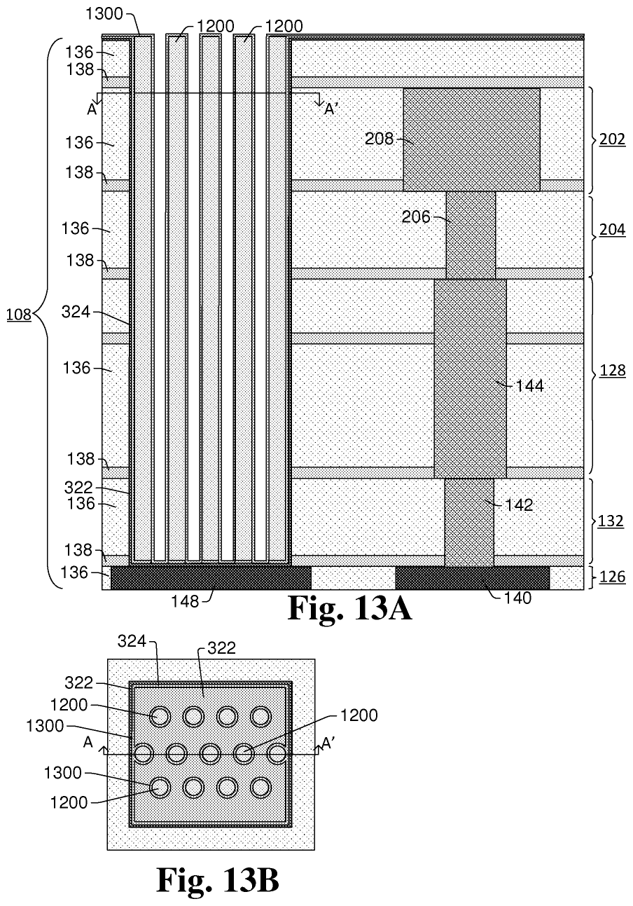

As shown in the cross-sectional and top views of FIGS. 13A-13B, a second capacitor bottom metal (CBM2) layer 1300, such as titanium nitride, is then conformally formed over the patterned shapes 1200 of the sacrificial layer and over the upper surface outside of the MIM recess. The second capacitor bottom metal layer 1300 can have the same material composition as the first capacitor bottom metal layer 324, and/or can have a different material composition from the first capacitor bottom metal layer 324. The second capacitor bottom metal layer 1300 covers an upper surface of the second conductive feature 148 and outer sidewalls and top surfaces of the patterned shapes of the sacrificial layer 1200.

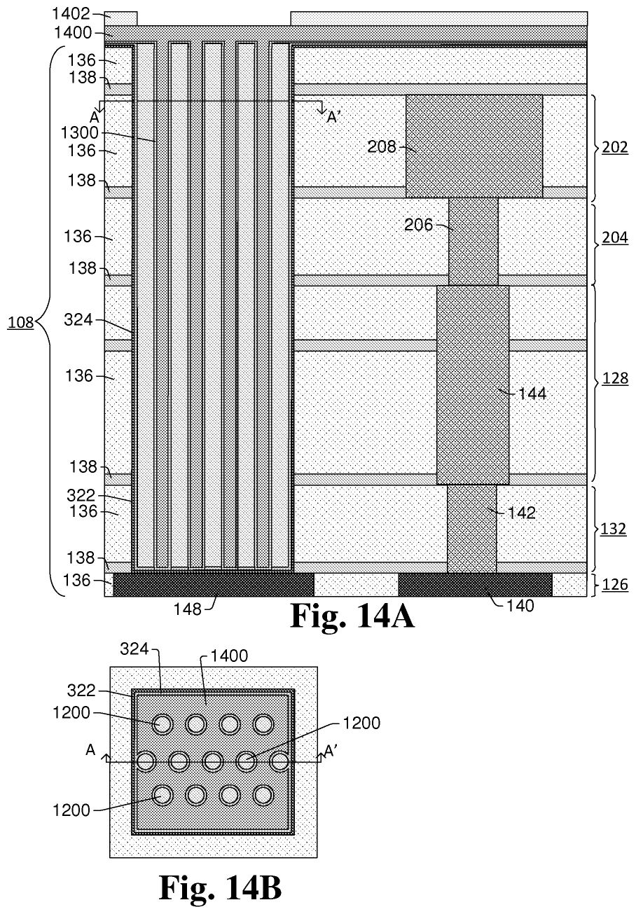

As shown in the cross-sectional and top views of FIGS. 14A-14B, a plug coating 1400 is then formed to fill in a remainder of the MIM capacitor trench and surrounds the patterned shapes of the sacrificial layer 1200. Photoresist 1402 is then formed and patterned over the plug coating 1402. In some embodiments, the plug coating 1400 can comprise or be photoresist. The plug coating 1400 can be the same type of photoresist or a different type of than photoresist 1402.

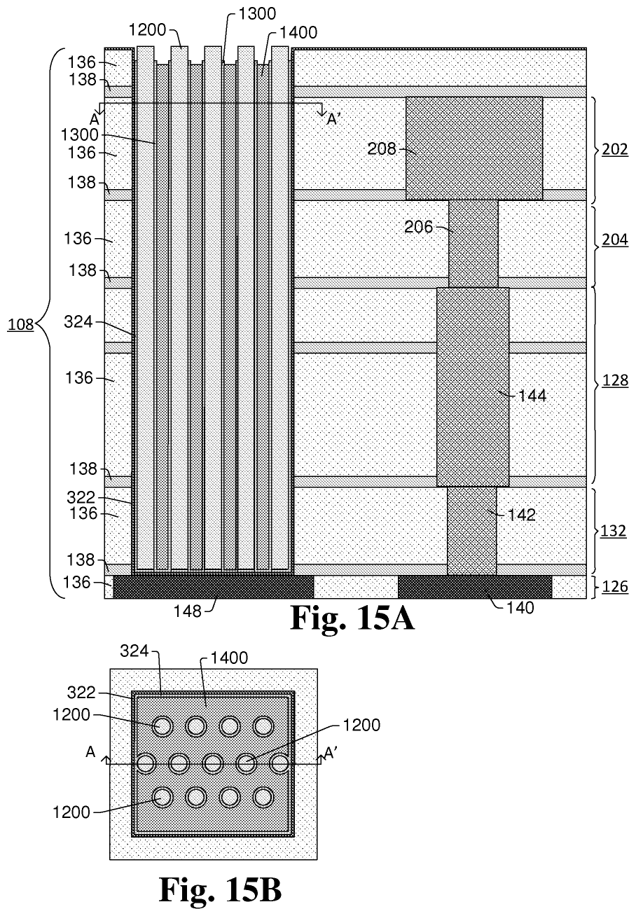

As shown in the cross-sectional and top views of FIGS. 15A-15B, an etch back process is performed. The etch back process removes the upper portions of the plug coating 1400, upper portions of first capacitor bottom metal layer 324, and upper portions of second capacitor bottom metal layer 1300, thereby exposing upper surfaces of the sacrificial layer 1200.

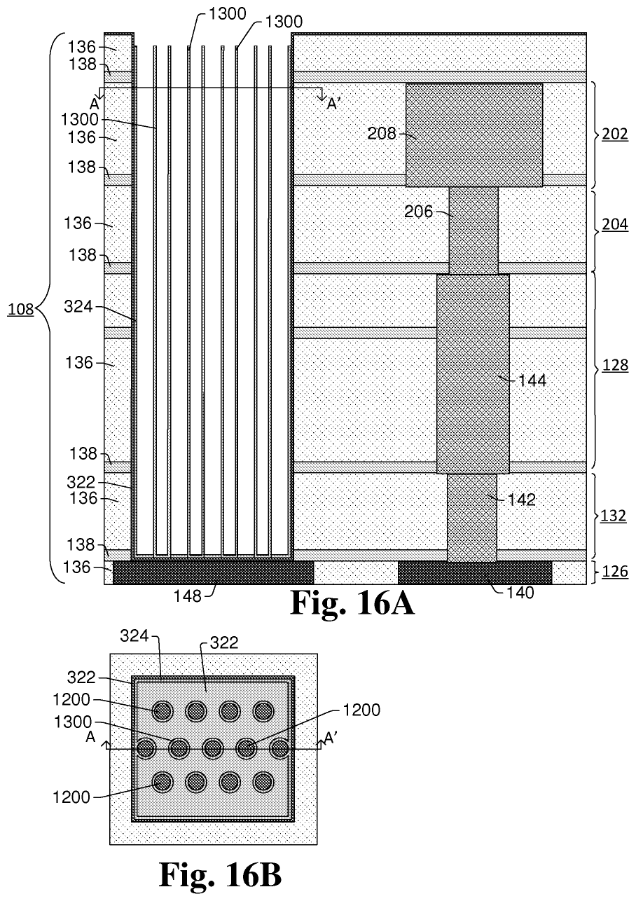

As shown in the cross-sectional and top views of FIG. 16A-16B, another etch is removed to remove the remaining sacrificial layer. Thus, this etch re-opens the MIM capacitor recess, albeit that the recess is now lined with the barrier layer 322, and first capacitor bottom metal layer 324. This etch also leaves a series of tubes, which are made of the first capacitor bottom metal layer material 1300, extending upward from a bottom surface of the MIM capacitor recess.

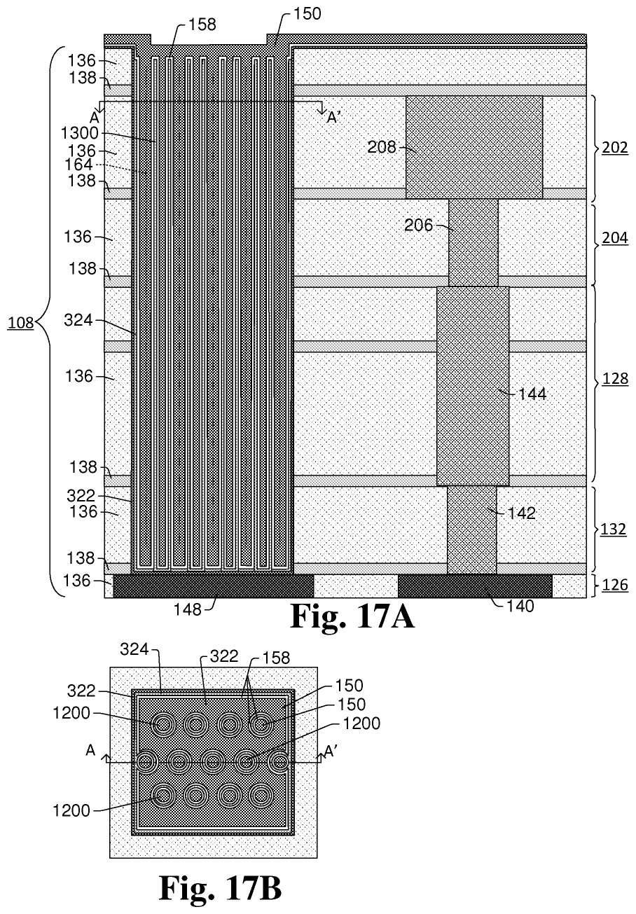

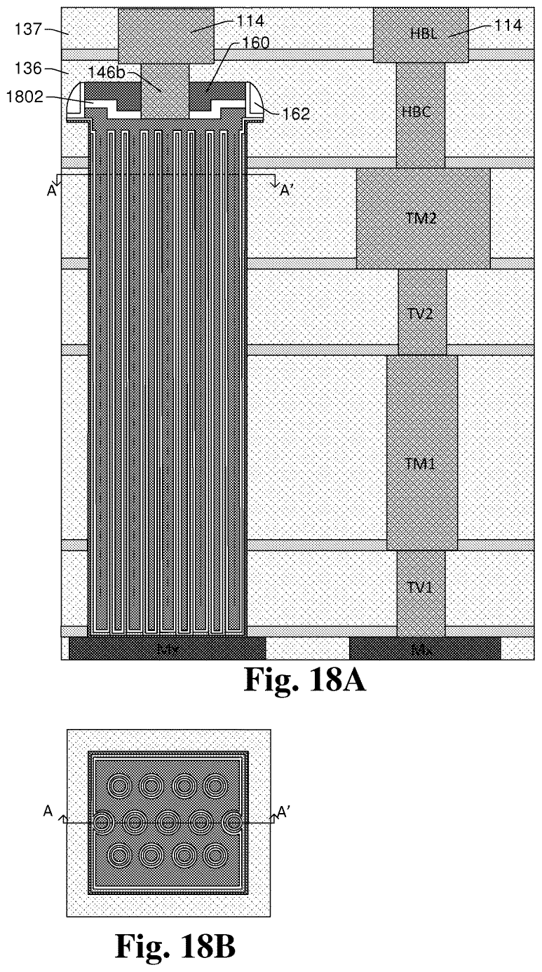

As shown in the cross-sectional and top views of FIG. 17A-17B, a capacitor dielectric 158 is formed over the structure of FIG. 16, and a capacitor top metal layer 150 is formed to fill the MIM capacitor recess. In some examples, the capacitor dielectric 158 is a high-K dielectric material, and the capacitor top metal 150 is or comprises titanium nitride. Air gaps 164 may be present during this fill in some cases.

As shown in the cross-sectional and top views of FIGS. 18A-18B, a dielectric layer 1802 and hard mask are 160 formed over the capacitor top metal layer 150 and are patterned using photolithography and an etch. A conformal dielectric liner and conformal spacer layer are then formed, and are then etched back to form sidewall spacers 162 that have lower surfaces that rest on the capacitor dielectric 158. An inter-layer (ILD) dielectric 136 is then formed, and a via 146b opening is formed through the ILD dielectric, hard mask, and dielectric; while another contact/via 146a is formed in the logic region of the circuit. A conductive via material is then formed to form upper contacts/vias 146b, and top dielectrics 137 and metal lines 114 are formed over the contacts.

As shown in the cross-sectional view of FIG. 19, the structure of FIG. 18 is bonded to another die/wafer 104. This bonding can involve at least two types of bonding: metal-to-metal bonding; and non-metal-to-non-metal bonding. In at least some embodiments, a process for performing the bonding comprises bonding individual surfaces respectively structure of FIG. 18 and the another die/wafer 104. In some embodiments, during the bonding, the top dielectric layers 136, 136 are bonded together through fusion bonding or the like and pads of the layers 114a, 114b and pads 116 are bonded together through metal-to-metal bonding or the like. In some embodiments, before the bonding, the process further comprises planarization (e.g., a CMP or the like), surface activation (e.g., plasma treatment or the like), cleaning, or the like to the surfaces to be bonded together.

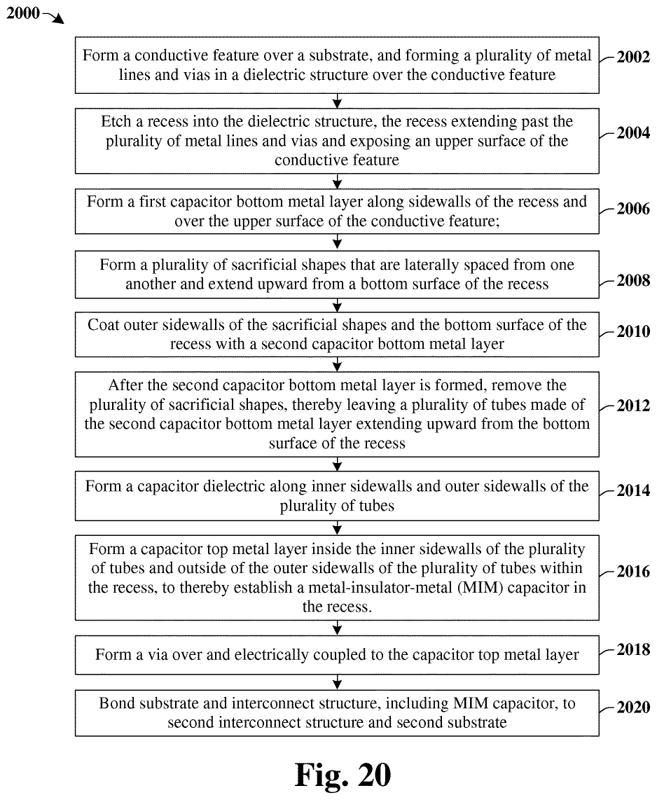

FIG. 20 illustrates a flowchart of some embodiments of a method of forming capacitors with a partial bottom landing on the contact wires. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2002, a conductive feature is formed over a substrate. The conductive feature can be a metal line, such as a top metal line in an interconnect structure, or can be a conductive gate or other conductive feature in an interconnect structure over a substrate. A plurality of metal lines and vias are formed in a dielectric structure over the conductive feature. In some embodiments, the conductive feature is formed over a capacitor region of the substrate, and the plurality of metal lines and vias are formed over a logic region of the substrate. See, for example, FIG. 10.

At 2004, a recess is etched into the dielectric structure. The recess extends past the plurality of metal lines and vias and exposes an upper surface of the conductive feature. See, for example, FIG. 10.

At 2006, a first capacitor bottom metal layer is formed along sidewalls of the recess and over the upper surface of the conductive feature. See, for example, FIG. 11.

At 2008, a plurality of sacrificial shapes are formed. The sacrificial shapes are laterally spaced from one another and extend upward from a bottom surface of the recess. See, for example, FIG. 12.

At 2010, outer sidewalls of the sacrificial shapes and the bottom surface of the recess are coated with a second capacitor bottom metal layer. See, for example, FIG. 13.

At 2012, after the second capacitor bottom metal layer is formed, the plurality of sacrificial shapes are removed. Thus, a plurality of tubes made of the second capacitor bottom metal layer are left extending upward from the bottom surface of the recess. See, for example, FIGS. 14-16.

At 2014, a capacitor dielectric is formed along inner sidewalls and outer sidewalls of the plurality of tubes. See, for example, FIG. 17.

At 2016, a capacitor top metal layer is formed inside the inner sidewalls of the plurality of tubes and outside of the outer sidewalls of the plurality of tubes within the recess, to thereby establish a metal-insulator-metal (MIM) capacitor in the recess. See, for example, FIG. 17.

At 2018, a via is formed over and electrically coupled to the capacitor top metal layer. See, for example, FIG. 18.

At 2020, the substrate and interconnect structure, including MIM capacitor, are bonded to second interconnect structure and second substrate. See, for example, FIG. 19.

Thus, some examples relate to a device including a semiconductor substrate. An interconnect structure is disposed over the semiconductor substrate. The interconnect structure includes a lower metal line and an upper metal line disposed at different heights over the semiconductor substrate, and a plurality of metal vias disposed at different respective heights from one another over the semiconductor substrate. A first electrode is disposed in the interconnect structure. The first electrode includes a first lateral portion and a protrusion that extends downward from the first lateral portion. The first lateral portion is disposed over an upper surface of the upper metal line, and the protrusion extends below a lower surface of the lower metal line. A second electrode is disposed in the interconnect structure and matingly engages the first electrode. The second electrode has a lower surface that is below a lower surface of the first electrode. A dielectric laterally surrounds an inner sidewall structure of the second electrode to separate the inner sidewall structure of the second electrode from an outer sidewall structure of the first electrode.

In some examples, the first electrode comprises a manifold portion and a plurality of protrusions that include the protrusion. The manifold portion extends downward from the first lateral portion and includes a plurality of openings defined by inner sidewalls of the manifold portion. The plurality of protrusions extend downward from the first lateral portion and are arranged respectively within the plurality of openings of the manifold portion.

In some examples, the plurality of protrusions each have a perimeter that is circular, square, square with rounded corners, rectangular, or rectangular with rounded corners when viewed from a top view.

In some examples, the dielectric is arranged along the inner sidewalls of the manifold portion and along outer sidewalls of the manifold portion.

In some examples, the second electrode includes a plurality of tubes that extend upward past at least three etch stop layers in the interconnect structure, wherein the dielectric is arranged along inner and outer sidewalls of the plurality of tubes.

In some examples, the plurality of tubes matingly engage the plurality of protrusions, respectively, and each of the plurality of tubes have a perimeter that is circular, square, square with rounded corners, rectangular, oval, or rectangular with rounded corners when viewed from a top view.

In some examples, the manifold portion has a first height, and each of the plurality of tubes have a second height that differs from the first height.

In some examples, the dielectric includes a first dielectric layer and a second dielectric layer that line different sidewalls and/or bottom surfaces in features of the device.

In some examples, a gap is disposed within the first electrode.

In some examples, a device includes a semiconductor substrate; a first conductive feature disposed at a first conductive feature height over a surface of the semiconductor substrate; and a first via disposed at a first via height over the surface of the semiconductor substrate. The first via is coupled to the first conductive feature, and the first via height is greater than the first conductive feature height. A first metal line is disposed at a first metal line height over the surface of the semiconductor substrate. The first metal line is coupled to the first via, and the first metal line height is greater than the first via height. A second via is disposed at a second via height over the surface of the semiconductor substrate. The second via is coupled to the first metal line, and the second via height is greater than the first metal line height. A second metal line is disposed at a second metal line height over the surface of the semiconductor substrate. The second metal line is coupled to the second via, and the second metal line height is greater than the second via height. A second conductive feature is disposed at the first conductive feature height over the surface of the semiconductor substrate. The second conductive feature is laterally spaced from the first conductive feature. A first electrode includes a first lateral portion and a protrusion that extends downward from the first lateral portion and is over the second conductive feature. The first lateral portion of the first electrode is disposed at a first electrode height that is greater than the first metal line height. The protrusion extends down to the first via height. A second electrode is disposed over the second conductive feature and extends upward from the second conductive feature to over the first metal line height. A dielectric laterally surrounds an inner sidewall structure of the second electrode to separate the inner sidewall structure of the second electrode from an outer sidewall structure of the first electrode.

In some examples, the first electrode includes a manifold portion and a plurality of protrusions that include the protrusion. The manifold portion extends downward from the first lateral portion and includes a plurality of openings defined by inner sidewalls of the manifold portion. The plurality of protrusions extend downward from the first lateral portion and are arranged respectively within the plurality of openings of the manifold portion.

In some examples, the dielectric is arranged along the inner sidewalls of the manifold portion and along outer sidewalls of the manifold portion.

In some examples, the second electrode includes a plurality of tubes that extend upward from the first conductive feature to over the second metal line height, wherein the dielectric is arranged along inner and outer sidewalls of the plurality of tubes.

In some examples, the plurality of tubes each have a perimeter that is circular, square, square with rounded corners, rectangular, oval, or rectangular with rounded corners when viewed from a top view.

In some examples, the manifold portion has a first height, and the plurality of tubes have a second height that differs from the first height.

In some examples, the dielectric includes a first dielectric layer and a second dielectric layer that line different sidewalls and/or bottom surfaces in features of the device.

In some examples, an air gap is disposed in an inner sidewall of the protrusion of the first electrode.

In some examples, a method includes an act of forming a conductive feature over a substrate, and forming a plurality of metal lines and vias in a dielectric structure over the conductive feature. A recess is etched into the dielectric structure. The recess extends past the plurality of metal lines and vias and exposes an upper surface of the conductive feature. A first capacitor bottom metal layer is formed along sidewalls of the recess and over the upper surface of the conductive feature. A plurality of sacrificial shapes that are laterally spaced from one another are formed and extend upward from a bottom surface of the recess. Outer sidewalls of the sacrificial shapes and the bottom surface of the recess are lined with a second capacitor bottom metal layer. After the second capacitor bottom metal layer is formed, the plurality of sacrificial shapes are removed to form a plurality of tubes made of the second capacitor bottom metal layer extending upward from the bottom surface of the recess. A capacitor dielectric is formed along inner sidewalls and outer sidewalls of the plurality of tubes. A capacitor top metal layer is formed inside the inner sidewalls of the plurality of tubes and outside of the outer sidewalls of the plurality of tubes within the recess, to thereby establish a metal-insulator-metal (MIM) capacitor in the recess.

In some examples, prior to forming the first capacitor bottom metal layer, a barrier layer is formed along sidewalls of the recess and over the upper surface of the conductive feature.

In some examples, forming the capacitor top metal layer includes leaving at least one air gap in the plurality of tubes.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment. Also, in some embodiments, the terms “approximately” and/or “about” can be interpreted as meaning +/−10%, while in other embodiments, the terms “approximately” and/or “about” can be interpreted as meaning within the normal fabrication tolerances of a given fab manufacturing flow.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a semiconductor substrate;
an interconnect structure disposed over the semiconductor substrate, the interconnect structure comprising a lower metal line, and an upper metal line disposed at different heights over the semiconductor substrate, and a plurality of metal vias disposed at different respective heights from one another over the semiconductor substrate;
a first electrode disposed in the interconnect structure, the first electrode including a first lateral portion and a protrusion that extends downward from the first lateral portion, the first lateral portion disposed over an upper surface of the upper metal line, and the protrusion extending below a lower surface of the lower metal line;
a second electrode disposed in the interconnect structure and matingly engaging the first electrode, the second electrode having a lower surface that is below a lower surface of the first electrode; and
a dielectric that laterally surrounds an inner sidewall structure of the second electrode to separate the inner sidewall structure of the second electrode from an outer sidewall structure of the first electrode.

2. The device of claim 1, wherein the first electrode comprises a manifold portion and a plurality of protrusions that include the protrusion, the manifold portion extending downward from the first lateral portion and including a plurality of openings defined by inner sidewalls of the manifold portion, and the plurality of protrusions extending downward from the first lateral portion and arranged respectively within the plurality of openings of the manifold portion.

3. The device of claim 2, wherein the plurality of protrusions each have a perimeter that is circular, square, square with rounded corners, rectangular, or rectangular with rounded corners when viewed from a top view.

4. The device of claim 2, wherein the dielectric is arranged along the inner sidewalls of the manifold portion and along outer sidewalls of the manifold portion.

5. The device of claim 2, wherein the second electrode includes a plurality of tubes that extend upward past at least three etch stop layers in the interconnect structure, wherein the dielectric is arranged along inner and outer sidewalls of the plurality of tubes.

6. The device of claim 5, wherein the plurality of tubes matingly engage the plurality of protrusions, respectively, and each of the plurality of tubes have a perimeter that is circular, square, square with rounded corners, rectangular, oval, or rectangular with rounded corners when viewed from a top view.

7. The device of claim 5, wherein the manifold portion has a first height, and each of the plurality of tubes have a second height that differs from the first height.

8. The device of claim 1, wherein the dielectric includes a first dielectric layer and a second dielectric layer that line different sidewalls and/or bottom surfaces in features of the device.

9. The device of claim 1, further comprising:
a gap disposed within the first electrode.

10. A device, comprising:
a semiconductor substrate;
a first conductive feature disposed at a first conductive feature height over a surface of the semiconductor substrate;
a first via disposed at a first via height over the surface of the semiconductor substrate, the first via coupled to the first conductive feature and the first via height being greater than the first conductive feature height;
a first metal line disposed at a first metal line height over the surface of the semiconductor substrate, the first metal line coupled to the first via and the first metal line height being greater than the first via height;
a second via disposed at a second via height over the surface of the semiconductor substrate, the second via coupled to the first metal line and the second via height being greater than the first metal line height;
a second metal line disposed at a second metal line height over the surface of the semiconductor substrate, the second metal line coupled to the second via and the second metal line height being greater than the second via height;
a second conductive feature disposed at the first conductive feature height over the surface of the semiconductor substrate, the second conductive feature laterally spaced from the first conductive feature;
a first electrode including a first lateral portion and a protrusion that extends downward from the first lateral portion and is over the second conductive feature, the first lateral portion of the first electrode disposed at a first electrode height that is greater than the first metal line height, and the protrusion extending down to the first via height;
a second electrode disposed over the second conductive feature and extending upward from the second conductive feature to over the first metal line height; and
a dielectric that laterally surrounds an inner sidewall structure of the second electrode to separate the inner sidewall structure of the second electrode from an outer sidewall structure of the first electrode.

11. The device of claim 10, wherein the first electrode comprises a manifold portion and a plurality of protrusions that include the protrusion, the manifold portion extending downward from the first lateral portion and including a plurality of openings defined by inner sidewalls of the manifold portion, and the plurality of protrusions extending downward from the first lateral portion and arranged respectively within the plurality of openings of the manifold portion.

12. The device of claim 11, wherein the dielectric is arranged along the inner sidewalls of the manifold portion and along outer sidewalls of the manifold portion.

13. The device of claim 11, wherein the second electrode includes a plurality of tubes that extend upward from the first conductive feature to over the second metal line height, wherein the dielectric is arranged along inner and outer sidewalls of the plurality of tubes.

14. The device of claim 13, wherein the plurality of tubes each have a perimeter that is circular, square, square with rounded corners, rectangular, oval, or rectangular with rounded corners when viewed from a top view.

15. The device of claim 13, wherein the manifold portion has a first height, and the plurality of tubes have a second height that differs from the first height.

16. The device of claim 10, wherein the dielectric includes a first dielectric layer and a second dielectric layer that line different sidewalls and/or bottom surfaces in features of the device.

17. The device of claim 10, further comprising:
an air gap disposed in an inner sidewall of the protrusion of the first electrode.

18. A method, comprising:
forming a conductive feature over a substrate, and forming a plurality of metal lines and vias in a dielectric structure over the conductive feature;
etching a recess into the dielectric structure, the recess extending past the plurality of metal lines and vias and exposing an upper surface of the conductive feature;
forming a first capacitor bottom metal layer along sidewalls of the recess and over the upper surface of the conductive feature;
forming a plurality of sacrificial shapes that are laterally spaced from one another and extend upward from a bottom surface of the recess;
coating outer sidewalls of the sacrificial shapes and the bottom surface of the recess with a second capacitor bottom metal layer;
after the second capacitor bottom metal layer is formed, removing the plurality of sacrificial shapes to form a plurality of tubes made of the second capacitor bottom metal layer extending upward from the bottom surface of the recess;
forming a capacitor dielectric along inner sidewalls and outer sidewalls of the plurality of tubes; and
forming a capacitor top metal layer inside the inner sidewalls of the plurality of tubes and outside of the outer sidewalls of the plurality of tubes within the recess, to thereby establish a metal-insulator-metal (MIM) capacitor in the recess.

19. The method of claim 18, further comprising:
prior to forming the first capacitor bottom metal layer, forming a barrier layer along sidewalls of the recess and over the upper surface of the conductive feature.

20. The method of claim 18, wherein forming the capacitor top metal layer includes leaving at least one air gap in the plurality of tubes.
